(19) United States
(12) Patent Application Publication
(10) Pub. No.: US 2007/0201597 A1
(43) Pub. Date: Aug. 30, 2007

(54) Sub-sampled digital programmable delay locked loop with triangular waveform preshaper

(76) Inventors: Hongkai He, Burlington (CA); Vasilis Papanikolaou, Toronto (CA); John Francis, Burlington (CA); Eric Iozsef, Toronto (CA); Mohammad H. Shakiba, Richmond Hill (CA); Fahim Adam Hasham, Unionville (CA)

Correspondence Address: David B. Cochran, Esq.;Jones Day, North Point, 901 Lakeside Avenue, Cleveland, OH, 44114, US

(21) Appl. No.: 11/649,097

(22) Filed: Jan. 3, 2007

Related U.S. Application Data
(60) Provisional application No. 60/755,944, filed on Jan. 3, 2006.

(51) Int. Cl. H03D 3/24

(52) U.S. Cl. 375/376

(57) ABSTRACT

A delay locked loop includes a triangle wave generator circuit coupled to a serial clock signal for generating a triangular wave signal. A phase interpolator coupled to the triangular wave signal and a weighting signal generates an interpolated clock phase signal, and a phase detector receives serial data and the interpolated clock phase signal and generates a retimed serial data signal.

### CROSS-REFERENCE TO RELATED APPLICATIONS

This application claims priority to U.S. Provisional Application Ser. No. 60/755,944, filed on Jan. 3, 2006, titled “Sub-Sampled Digital Programmable Delay Locked Loop with Triangular Waveform Preshaper.” The entirety of this prior application is hereby incorporated into this patent application by reference.

### BACKGROUND

Delay locked loops (DLLs) may be used in various data transmission applications to generate a retimed data signal from a transmitted serial data stream and a serial clock signal. Data recovery problems are often associated with DLLs, however, primarily due to phase signals not being generated linearly over a wide range of input frequencies. Other problems may include: i) retiming of the serial data stream when clock and data skew is undetermined; ii) the complexity of the phase interpolator block of the DLL; iii) the DLL bandwidth not being low enough; and iv) operating the DLL at high-speed serial data rates.

### SUMMARY

A delay locked loop includes a triangle wave generator circuit coupled to a serial clock signal for generating a triangular wave signal. A phase interpolator coupled to the triangular wave signal and a weighting signal generates an interpolated clock phase signal, and a phase detector receives serial data and the interpolated clock phase signal and generates a retimed serial data signal.

### BRIEF DESCRIPTION OF THE DRAWINGS

FIG. 1 is a block diagram of an example sub-sampled delay locked loop having a triangular waveform preshaper;

FIG. 2A is a timing diagram showing the generation of low slew-rate I/Q triangular waveforms from the input I/Q serial clock signals;

FIG. 2B is a timing diagram showing the generation of high slew-rate I/Q triangular waveforms from the input I/Q serial clock signals; and

FIG. 3 is an example phase interpolator for use in the DLL of FIG. 1.

### DETAILED DESCRIPTION

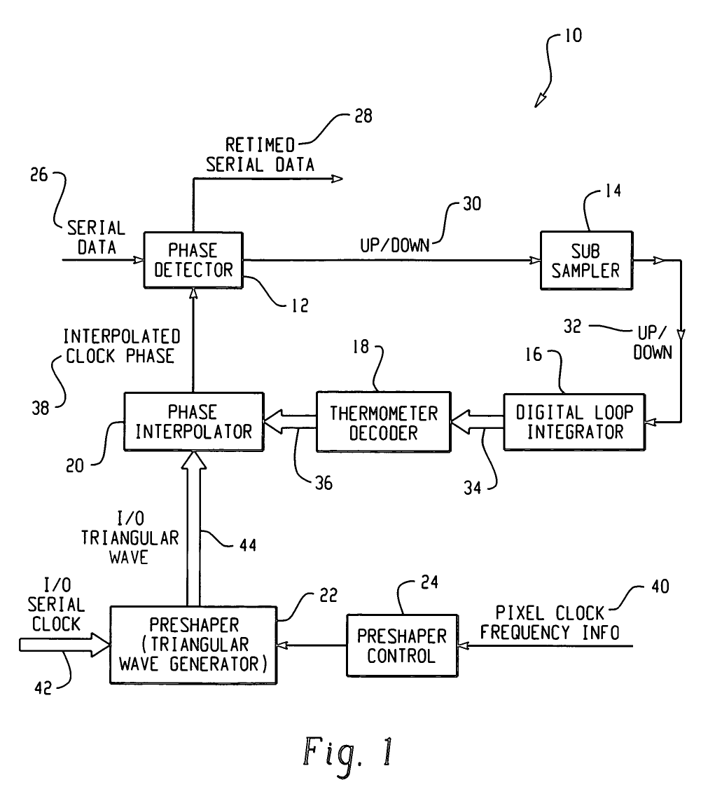

FIG. 1 is a block diagram of an example sub-sampled delay locked loop 10 having a triangular waveform preshaper 22. The DLL circuitry includes, in addition to the triangular waveform preshaper 22, a preshaper control circuit 24, a phase interpolator 20, a phase detector 12, a sub-sampler 14, a digital loop integrator 16, and a thermometer decoder 18. The phase detector 12, sub-sampler 14, digital loop integrator 16, thermometer decoder 18 and phase interpolator 20 form a delay locked loop. The phase interpolator 20 is controlled by a data word 36 from the thermometer decoder 18, which is used to generate an interpolated clock phase signal 38 from I/Q triangular wave inputs 44 provided by the triangular waveform preshaper 22.

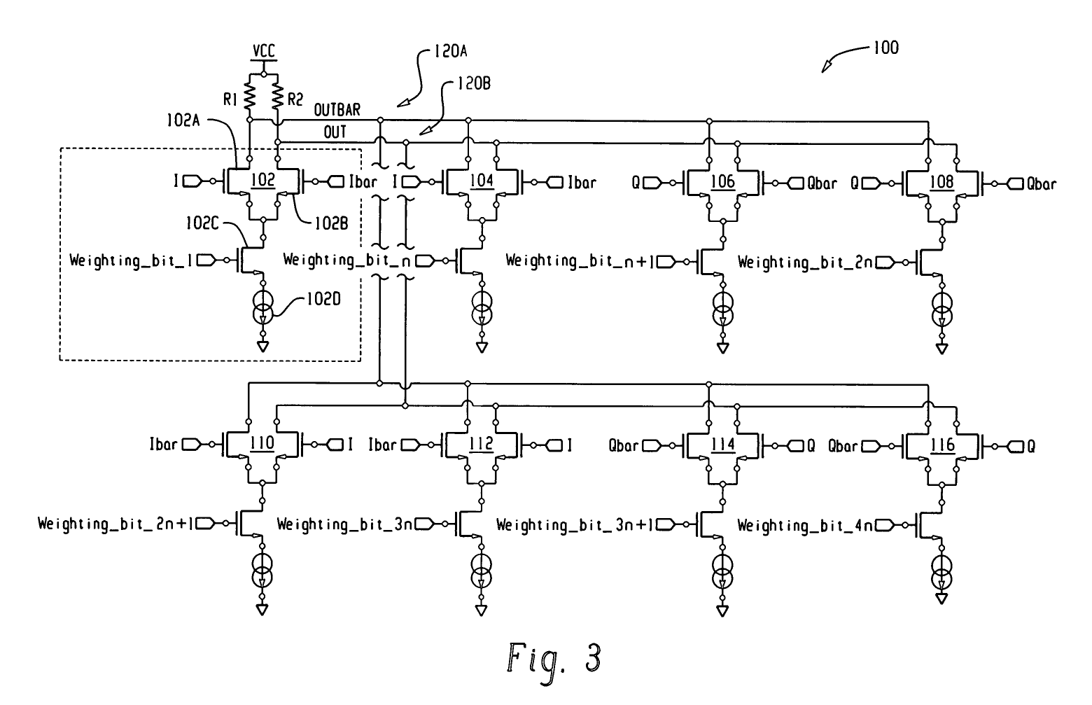

In the example sub-sampled DLL shown in FIG. 1, a desired phase—the interpolated clock phase 38—is generated by combining two digitally-weighted triangular serial-clock-rate waveforms 44 in a novel phase interpolator 20. The phase interpolator sums the digitally weighted currents of I, Q, Ibar and the Qbar signals. An example of the novel phase interpolator 20 is shown in FIG. 3, discussed in more detail below. The weighting information 36 is thermometer-coded. Triangular waveforms 44 are preferably generated because they are easier to generate than sine waves, and also because the addition of two triangular waveforms into linearly-spaced phase steps is easier than the addition of sine or rectangular waves.

The phase interpolator 20 provides the interpolated clock phase signal 38 to the phase detector 12, which also receives the input serial data stream 26. In a preferred implementation, the serial data stream may be digitally encoded video data such as HDMI or DVI encoded picture and control information. The phase detector then generates the retimed serial data 28 in response to these two inputs, and also generates an up/down phase control signal 30 which indicates the direction of phase skew between the interpolated clock phase signal 38 and the input serial data signal 26. This signal 30 is sampled 14, integrated 16 and decoded 18 in order to control the phase interpolator 20 so that the interpolated clock phase signal 38 is exactly in phase with the input serial data signal 26.

Generating the interpolated clock phase signal 38 begins with the I/Q serial clock signals 42, which are provided to the triangular wave generator 22. The preshaper 22 shapes the in-phase and quadrature serial clocks 42 into triangular waveforms in response to a preshaper control signal that ensures a relatively constant swing of the triangular waveforms 44. The preshaper control block 22 controls the slew rate of the triangular waveforms 44 based on the frequency information of a pixel clock 40 (in the example of a video implementation) to ensure a relatively constant swing and non-clipped waveform output of the preshaper 22. The slew rate is proportional to the frequency so that the swing is constant. In an alternate embodiment, an AGC (Auto Gain Control) circuit may be employed to ensure a constant swing across different frequencies.

The phase detector 12, sub-sampler 14, digital loop integrator 16, decoder 18 and the phase interpolator 20 form the delay locked loop. The digital-weighted phase interpolator 20 interpolates the I/Q triangular waves 44 produced by the pre-shaper 22 based on the weighting information coming for the thermometer decoder 18. Thermometer-coded weighting information is used to eliminate spurs when changing phases. The phase detector compares the phase of the serial data 26 and the interpolated clock phase signal 38 and splits out the retimed data signal 28 and the up/down phase control signal 30. Subsequently, the up/down phase control signal 30 is sub-sampled in the sub-sampler 14 and then integrated in the digital loop integrator 16. This results in a binary coded integration signal 34, which is converted into the thermometer-coded signal 36 by the decoder 18. Based on the updated thermometer code 36, the phase interpolator then generates the next interpolated clock phase 38 and the entire looping process continues.

The example DLL shown in FIG. 1 is designed such that it operates digitally. The digital loop integration 16 and digital phase decoder 18 enable implementation using the standard CMOS libraries. Additionally, a programmable and very low (kHz range) loop bandwidth can be easily realized because the loop integration is digital instead of analog. Furthermore, sub-sampling of the up/down signal 30 reduces the requirement of the loop and its circuitry speed. Portability to other processes is also facilitated by the digital implementation. Finally, working with the data in serial domain facilitates higher resolution, and smaller phase step sizes can be achieved.

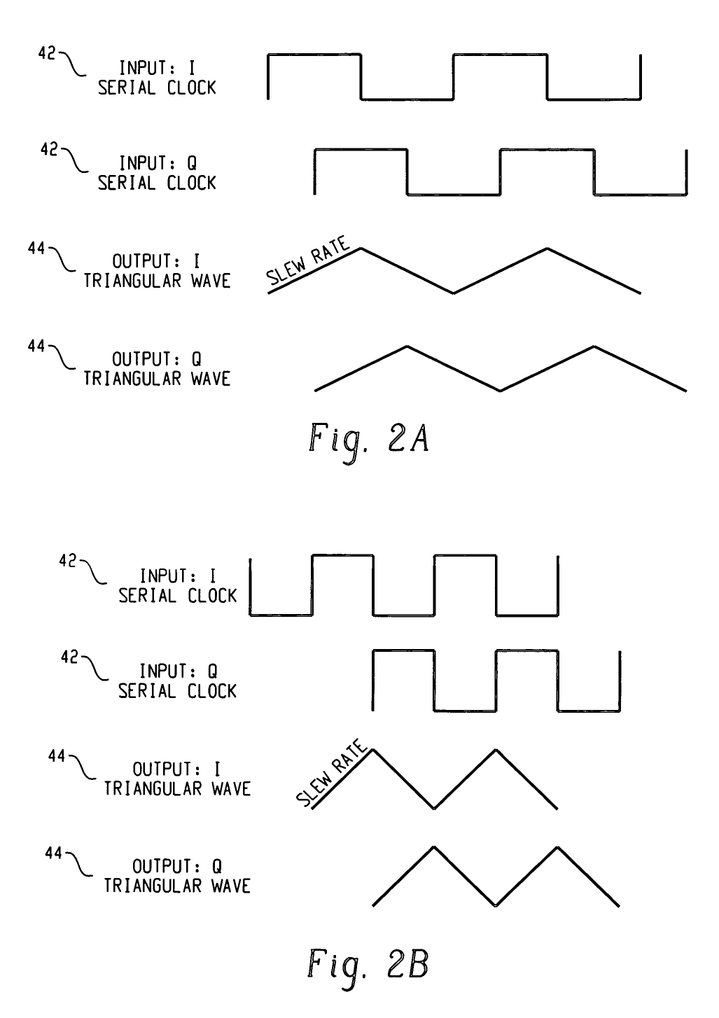

FIG. 2A is a timing diagram showing the generation of low slew-rate I/Q triangular waveforms 44 from the input I/Q serial clock signals 42. FIG. 2B is a timing diagram showing the generation of high slew-rate I/Q triangular waveforms 44 from the input I/Q serial clock signals 42. As shown in these two figures, although the slew rates of the triangular waveforms 44 may change, based upon the frequency information 40 provided by the preshaper control block 42, the relative amplitude of the signals 44 remains constant.

FIG. 3 is an example phase interpolator 100 for use in the DLL of FIG. 1. This phase interpolator 100 includes a plurality of differential current switches 102, 104, 106, 108, 110, 112, 114 and 116, whose current outputs are coupled in parallel to a common set of drain resistors R1, R2 which form the output signals 120A, 120B of the circuit. Each of the differential current switches, such as switch 102, comprises a pair of common-source FETs 102A, 102B, a control transistor 102C, and a current source 102D. Each of the common-source FETs is connected to one of the I, Ibar, Q, and Qbar triangular waveform signals 44 from the preshaper 22. The control transistor 102C is turned on/off, thereby allowing current to flow through one of the common-source FETs 102A, 102B, by a weighted output bit from the thermometer decoder 36. This “weighting bit” controls the on/off state of each differential pair, and is coded in a thermometer coding scheme so as to avoid spikes in the output signal when the phase changes abruptly. For each of the control transistors 102C that is turned “on” by the thermometer decoder 36, current from the current source 102D flows through one of the common-source FETs 102A, 102B, and is summed at the common drain junctions (OUT, OUTBAR) thereby adding to any other currents flowing though the same transistor and generating a corresponding voltage drop across R1 or R2. This voltage drop then forms the digitally-weighted interpolated clock phase signal 38, which is provided to the phase detector 12.

The example implementation herein is portable to other technologies and can work with a wide range of data rates. Power consumption and area requirements are reduced over known DLLs. The phase obtained using this implementation is accurate with respect to the serial data. In addition, small phase steps, of down to a few percent of the serial data period, can be achieved. Moreover, the sub-sampling rate, loop bandwidth and swing of the triangular waveforms 44 may be programmable.

The steps and the order of the steps in the methods and flowcharts described herein may be altered, modified and/or augmented and still achieve the desired outcome. Additionally, the methods, flow diagrams and structure block diagrams described herein may be implemented in the example processing devices described herein by program code comprising program instructions that are executable by the device processing subsystem. Other implementations may also be used, however, such as firmware or even appropriately designed hardware configured to carry out the methods or implement the structure block diagrams described herein. Additionally, the method and structure block diagrams that describe particular methods and/or corresponding acts in support of steps and corresponding functions in support of disclosed software structures may also be implemented in software stored in a computer readable medium and equivalents thereof. The software structures may comprise source code, object code, machine code, or any other persistently or temporarily stored code that is operable to cause one or more processing systems to perform the methods described herein or realize the structures described herein.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art-may effect alterations, modifications and variations to the examples without departing from the scope of the invention.

What is claimed is:

1. A delay locked loop system, comprising:
a triangle wave generator circuit configured to receive in-phase and quadrature serial clock signals and generate in-phase and quadrature triangle wave signals;
a preshaper control circuit coupled to the triangle wave generator circuit and configured to receive pixel clock information and generate a control signal to control the slew rate of the in-phase and quadrature triangle wave signals;
a digital phase interpolator circuit configured to receive a weighting signal and receive and interpolate the in-phase and quadrature triangle wave signals and generate an interpolated clock phase signal;
a phase detector circuit configured to receive serial data and compare the phase of the serial data and the interpolated clock phase signal and generate retimed serial data and an up/down signal;
a sub-sampler circuit configured to receive and sub-sample the up/down signal to generate a sub-sampled up-down signal;
a digital loop integrator circuit configured to receive the sub-sampled up-down signal and generate a binary coded integration signal; and
a thermometer decoder circuit configured to receive the binary coded integration signal and generate a weighting signal.

2. The delay locked loop system of claim 1, wherein the weighting signal from the thermometer decoder is a multi-bit thermometer coded signal.

3. The delay locked loop system of claim 2, wherein the digital phase interpolator comprises a plurality of differential current switches coupled to a plurality of controllable current sources, wherein the plurality of controllable current sources are coupled to the multi-bit thermometer coded signal and the differential current switches are coupled to the in-phase and quadrature phase triangle wave signals.

4. The delay locked loop system of claim 1, wherein the serial data is HDMI or DVI encoded video data.

5. A delay locked loop, comprising:
a triangle wave generator circuit coupled to a serial clock signal for generating a triangular wave signal;
a phase interpolator coupled to the triangular wave signal and a weighting signal for generating an interpolated clock phase signal; and
a phase detector for receiving serial data and the interpolated clock phase signal and for generating a retimed serial data signal.

6. The delay locked loop of claim 5, further comprising:
a sub-sampler for receiving an up/down phase control signal from the phase detector and for generating a sub-sampled up/down phase control signal;
an integrator for receiving the sub-sampled phase control signal and for generating a binary coded integration signal; and
a thermometer decoder for receiving the binary coded integration signal and for generating the weighting signal.

7. The delay locked loop of claim 5, wherein the triangle wave generator receives in-phase and quadrature phase serial clock signals and generates in-phase and quadrature phase triangle wave signals.

8. The delay locked loop of claim 7, further comprising:
a preshaper control circuit coupled to the triangle wave generator circuit and configured to receive frequency information and generate a control signal to control the slew rate of the in-phase and quadrature phase triangle wave signals.

9. The delay locked loop of claim 7, wherein the phase interpolator generates the interpolated clock phase signal based upon the in-phase and quadrature phase triangle wave signals.

10. The delay locked loop of claim 7, wherein the weighting signal from the thermometer decoder is a multi-bit thermometer coded signal.

11. The delay locked loop of claim 10, wherein the phase interpolator comprises a plurality of differential current switches coupled to a plurality of controllable current sources, wherein the plurality of controllable current sources are coupled to the multi-bit thermometer coded signal and the differential current switches are coupled to the in-phase and quadrature phase triangle wave signals.

12. The delay locked loop of claim 1, wherein the serial data is HDMI or DVI encoded video data.

13. A method of recovering serial data in a delay locked loop having a phase detector that receives a serial data stream and generates a retimed serial data stream, comprising:
outputting an up/down phase control signal from the phase detector;
sub-sampling the up/down phase control signal to form a sub-sampled up/down phase control signal;
integrating the sub-sampled up/down phase control signal to form a binary coded integration signal;
decoding the binary coded integration signal into a digitally weighted thermometer coded signal; and
generating an interpolated clock phase signal that controls the generation of the retimed serial data stream in the phase detector, the interpolated clock phase signal being generated by digitally weighting in-phase and quadrature phase triangular waveform signals formed from in-phase and quadrature phase clock signals.

14. A method of retiming a serial data stream, comprising:
generating in-phase and quadrature phase triangular waveforms from received in-phase and quadrature phase clock signals;
generating an interpolated clock phase signal from the in-phase and quadrature phase triangular waveforms and from a digitally-weighted thermometer coding signal; and
retiming a received serial data stream using the interpolated clock phase signal.

15. The method of claim 14, further comprising:
controlling the slew rate of the in-phase and quadrature phase triangular waveforms based upon frequency information of the serial data.

16. The method of claim 14, further comprising:
generating an up/down phase control signal;
sub-sampling the up/down phase control signal to form a sub-sampled signal;
integrating the sub-sampled signal to form a binary integrated signal; and
generating the digitally-weighted thermometer coding signal based upon the binary integrated signal.

17. The method of claim 14, wherein the received serial data stream is an HDMI or DVI encoded data stream.
